(19) United States
(12) Patent Application Publication
(10) Pub. No.: US 2002/0060352 A1
(43) Pub. Date: May 23, 2002

(54) Semiconductor integrated circuit

(76) Inventor: Kanji Mizuno, Tokyo (JP)

Correspondence Address: LEYDIG VOIT & MAYER, LTD, 700 THIRTEENTH ST. NW, SUITE 300, WASHINGTON, DC, 20005-3960, US

(21) Appl. No.: 09/829,910

(22) Filed: Apr. 11, 2001

(30) Foreign Application Priority Data
Nov. 22, 2000 (JP) 2000-355883

(51) Int. Cl. H01L 29/76

(52) U.S. Cl. 257/537; 257/536; 257/379

(57) ABSTRACT

The semiconductor integrated circuit has a TaN layer as a trimming device. Current trimming and laser trimming can be performed on this TaN layer. A part of a metal wiring layer is removed to expose a TaN layer functioning as a metal barrier of the metal wiring layer provided on the TaN layer, thereby obtaining a TaN single layer portion. The TaN single layer portion is used as a resistor for trimming functioning as a fuse.

### FIELD OF THE INVENTION

The present invention in general relates to a semiconductor integrated circuit having a trimming device for trimming a circuit characteristic. More particularly, this invention relates to a semiconductor integrated circuit of which circuit characteristic has to be set with high precision by trimming.

### BACKGROUND OF THE INVENTION

In a semiconductor integrated circuit, to realize a circuit operation as designed, each of nonlinear devices such as diode and transistor and linear devices such as resistor and capacitor constructing the circuit has to have a characteristic as designed at a designing stage. Usually, since processes under the same conditions are performed on the same semiconductor substrate, each of the devices fabricated by a semiconductor fabricating process can precisely realize a required numerical value with respect to relative precision of the characteristic.

With respect to the absolute precision of the characteristic of each device, however, it always varies from 20% to 30%. Usually, after completion of the process, trimming is performed on a device of which absolute precision of a characteristic value has to be lower than the variation range from the viewpoint of the characteristic of the circuit, such as a resistor for setting the gain of an operational amplifier.

As conventional existing trimming techniques, Zener zapping and laser trimming are known, which are realized by forming a trimming device near a device required to have the absolute precision at the fabricating stage of a semiconductor integrated circuit. The trimming device is generally connected in parallel with a resistor which determines the characteristic of the device required to have the absolute precision. The trimming techniques are selectively used according to the kind of the trimming device and a process to be performed.

The Zener zapping is a method of trimming a device characteristic by using a nonlinear device having a PN junction such as a bipolar transistor or diode as a trimming device and establishing a short circuit by passing a heavy current to the PN junction. FIGS. 5A and 5B are diagrams for explaining the Zener zapping.

As shown in FIG. 5A, a resistor R is a device for determining the characteristic of a device required to have the absolute precision and is, for example, a resistor for setting the gain of an operational amplifier. A diode T functioning as a trimming device is connected in parallel with the resistor R. FIG. 5B is a diagram showing the layout of a portion corresponding to the thick-lined frame 100 in FIG. 5A. As shown in FIG. 5B, the diode T is realized by short-circuiting the collector (C) and the base (B) of a bipolar transistor.

In FIGS. 5A and 5B, the trimming by the Zener zapping is performed by passing a heavy current between pads P11 and P12 led from both ends of the diode T in a reverse bias manner. It makes the temperature of a PN junction 101, that is, the temperature in a portion between the base (B) and the emitter (E) in FIG. 5B increase and further nonuniform diffusion, crystal defect, nonuniform thermal diffusion, and the like occurs, so that a region called a hot spot in which the temperature increases locally is generated and the current is concentrated in the region.

When the temperature of the region reaches the intrinsic temperature at which increase in carriers is caused, a junction breakdown occurs. By aluminum melt by the subsequent current, a short circuit called a filament is formed between the anode and the cathode. Due to the formation of the filament T′, the resistor R is short-circuited and can be eliminated from a required value for determining the device characteristic. As a result, it denotes that the characteristic of the device required to have the absolute precision can be trimmed.

The Zener zapping has effective advantages such that, since a transistor or diode is used as the trimming device, a semiconductor fabricating process can be used so that no new process has to be added, and a zapping device can be relatively easily constructed and can be mounted on an ordinary wafer tester.

On the other hand, laser trimming can be divided broadly into two methods according to whether the material of the trimming device is polysilicon or aluminum. First, polysilicon laser trimming using a trimming device made of polysilicon is a method of fusing the polysilicon by irradiation of a laser beam. FIG. 6 is a diagram for explaining the polysilicon laser trimming and particularly shows the layout cross section of a semiconductor integrated circuit using a polysilicon layer as a trimming device.

As shown in FIG. 6, generally, a MOS transistor has a multilayer structure in which an SiO₂ layer 112 as an insulating interlayer, a polysilicon layer 118 serving as a gate electrode, a BPSG (Boro-Phospho-Silicate-Glass) layer 113 and an SiO layer 114 as insulating interlayers, and a glass coating layer 117 as a protective film are stacked on a silicon substrate 111. The polysilicon laser trimming is performed by using a part of the polysilicon layer 118 as a trimming device. As a specific layout, for example, the polysilicon layer 118 is disposed so as to short-circuit a resistor which becomes effective after trimming.

The polysilicon laser trimming is performed by opening a window 130 in a part of the glass coating layer 117 as shown in the diagram, and a laser beam is emitted toward the polysilicon layer 118 as a lower layer through the window 130. It makes the temperature of the region irradiated with the laser beam in the polysilicon layer 118 increase, and the region is fused. That is, a resistor connected in parallel with a line made by the polysilicon layer 118 becomes effective.

According to the method, in a manner similar to the polysilicon laser trimming, the chip area can be reduced. Moreover, since the process is performed in the wiring process, there is an advantage such that the method does not depend on an underlayer process.

In the Zener zapping, however, as shown in FIGS. 5A and 5B, at least two pads for zapping have to be provided for trimming one part. Consequently, when the number of trimming parts is large, a problem such that the chip size increases arises. Since the characteristic of a transistor or diode varies according to processes, it is necessary to optimize zapping conditions for each process. Particularly, accurate adjustment of a current is important. When the conditions are not satisfied only a little, problems such that a filament is not formed, aluminum is jetted, and the like occur.

Since a junction breakdown which is inherently unpreferable is positively used in a semiconductor integrated circuit which can be subjected to Zener zapping, an accurate reliability test has to be conducted. It is difficult to realize both easy handling and reliability of short-circuiting.

Application of the polysilicon laser trimming is basically limited to a semiconductor integrated circuit of an MOS type such as CMOS, BiCMOS, or DMOS which is fabricated by a method including a polysilicon process. That is, in the case of applying the polysilicon laser trimming to a bipolar type semiconductor integrated circuit, it is necessary to newly add a polysilicon process in the fabricating process for the circuit.

As shown in FIG. 6, when the BPSG layer 113, SiO layer 114, and the like positioning on and over the polysilicon layer 118 are thick, it is difficult to adjust a laser beam, so that a case where the polysilicon layer 118 is not perfectly fused or a case where, due to too strong laser intensity, the laser beam penetrates the SiO₂ layer and the fused polysilicon and silicon substrate 11 maybe short-circuited. It is not preferable from the viewpoint of reliability that the window 130 is formed in the upper layers of the polysilicon layer 118, that is, the BPSG layer 113 and the SiO layer 114 in the diagram to expose the polysilicon layer 118 since there are problems such as occurrence of noise and corrosion.

Further, for the semiconductor integrated circuit having the polysilicon layer 118, a method of fusing the polysilicon functioning as the trimming device by using not a laser beam but a current can be also considered. Since the other insulating interlayer is provided on the polysilicon layer 118, however, it is concerned that a damage such as a crack due to sudden heating occurs. As the other insulating interlayer is provided on the polysilicon layer 118, it is considered that there is a problem such that a fusing condition has to be more strictly set as compared with the case where the polysilicon layer 118 is exposed.

The above-described aluminum laser trimming has problems such that conditions at the time of fusing have to be adjusted due to reflection of aluminum and the like and a measure against corrosion of aluminum is necessary since a fused portion is exposed. To a semiconductor integrated circuit using aluminum wiring as a trimming device, only trimming using a laser beam can be applied for the following reason. Even if aluminum wiring is routed, its resistance is only a few ohms. In order to fuse the aluminum wire by a current, a current in the order of ampere has to be passed, so that this is not realistic. For example, at the time of a failure in a laser trimming apparatus or a trouble in a process at the time of mass production such as a crowded state or the like, a problem such that other trimming means cannot be used instead occurs.

### SUMMARY OF THE INVENTION

It is an object of this invention to obtain a semiconductor integrated circuit having a tantalum nitride (hereinbelow, referred to as TaN) film as a trimming device, on which both current trimming and laser trimming can be performed.

The semiconductor integrated circuit according to this invention has a tantalum nitride film formed as a barrier metal of a metal wiring layer. Furthermore, the semiconductor integrated circuit includes a resistor for trimming made by a single layer portion of the tantalum nitride film formed by removing a part of the metal wiring layer.

According to the present invention, the tantalum nitride single layer portion is obtained by removing a part of the metal wiring layer provided on the tantalum nitride layer functioning as a barrier metal of the metal wiring layer. Consequently, the tantalum nitride single layer portion can be used as a resistor for trimming which functions as a fuse.

Furthermore, it is preferable that the resistor for trimming is made by the single layer portion of the tantalum nitride film, one of faces of the single layer portion is exposed, and the resistor for trimming can be burnt when the one face is irradiated with a laser beam.

Since the resistor for trimming is obtained by exposing one of the faces of the tantalum nitride single layer portion, the resistor for trimming can be used as a laser trimming device which is burnt when the one face is irradiated with a laser beam.

Furthermore, it is preferable that the semiconductor integrated circuit is further provided with electrode pads led from both ends of the resistor for trimming. In addition, the resistor for trimming is made by a single layer portion of the tantalum nitride film, one of faces of the single layer portion is exposed, and the resistor for trimming is burnt when a current is passed to the electrode pads.

Thus, the resistor for trimming is made by a single layer portion of the tantalum nitride film, and the electrode pads led from both ends of the resistor for trimming are provided. Consequently, the resistor for trimming can be used as a current trimming device which is burnt when a current is passed to the electrode pads.

Furthermore, it is preferable that the semiconductor integrated circuit is further provided with electrode pads led from both ends of the resistor for trimming. In addition, the resistor for trimming is made by a single layer portion of the tantalum nitride film, one of faces of the single layer portion is exposed, and the resistor for trimming is burnt when the face is irradiated with a laser beam or a current is passed to the electrode pads.

Thus, the resistor for trimming is made by exposing one of the faces of the single layer portion of the tantalum nitride film and the electrode pads led from both ends of the resistor for trimming are provided. The resistor for trimming can be therefore used both as a laser trimming device which is burnt when the face is irradiated with a laser beam and a current trimming device which is burnt when a current is passed to the electrode pads.

Furthermore, it is preferable that the semiconductor integrated circuit is further provided with a transistor for passing a current to the resistor for trimming. In addition, the resistor for trimming is made by a single layer portion of the tantalum nitride film, one of faces of the single layer portion is exposed, and the resistor for trimming is burnt when the transistor is turned on.

Thus, the transistor for passing a current is connected to the resistor for trimming which is provided as the single layer portion of the tantalum nitride film, of which one face is exposed. By turning on the transistor, the resistor trimming can be therefore burnt.

Furthermore, it is preferable that the semiconductor integrated circuit is further provided with a transistor for passing a current to the resistor for trimming. In addition, the resistor for trimming is made by a single layer portion of the tantalum nitride film, one of faces of the single layer portion is exposed, and the resistor for trimming is burnt when the face is irradiated with a laser beam or the transistor is turned on.

Thus, the transistor for passing a current is connected to the resistor for trimming provided as the single layer portion of the tantalum nitride film, of which one face is exposed. Consequently, the resistor for trimming can be used both as a laser trimming device which is burnt when the face is irradiated with a laser beam and as a current trimming device which is burnt when the transistor is turned on.

Other objects and features of this invention will become apparent from the following description with reference to the accompanying drawings.

### BRIEF DESCRIPTION OF THE DRAWINGS

FIG. 1 is a diagram for explaining a trimming device in a semiconductor integrated circuit according to a first embodiment.

FIG. 2 is a diagram for explaining laser trimming in a semiconductor integrated circuit according to a second embodiment.

FIGS. 3A and 3B are diagrams for explaining current trimming in a semiconductor integrated circuit according to a third embodiment.

FIG. 4 is a diagram showing an example of the configuration of a semiconductor integrated circuit according to a fourth embodiment.

FIGS. 5A and 5B are diagrams for explaining Zener zapping.

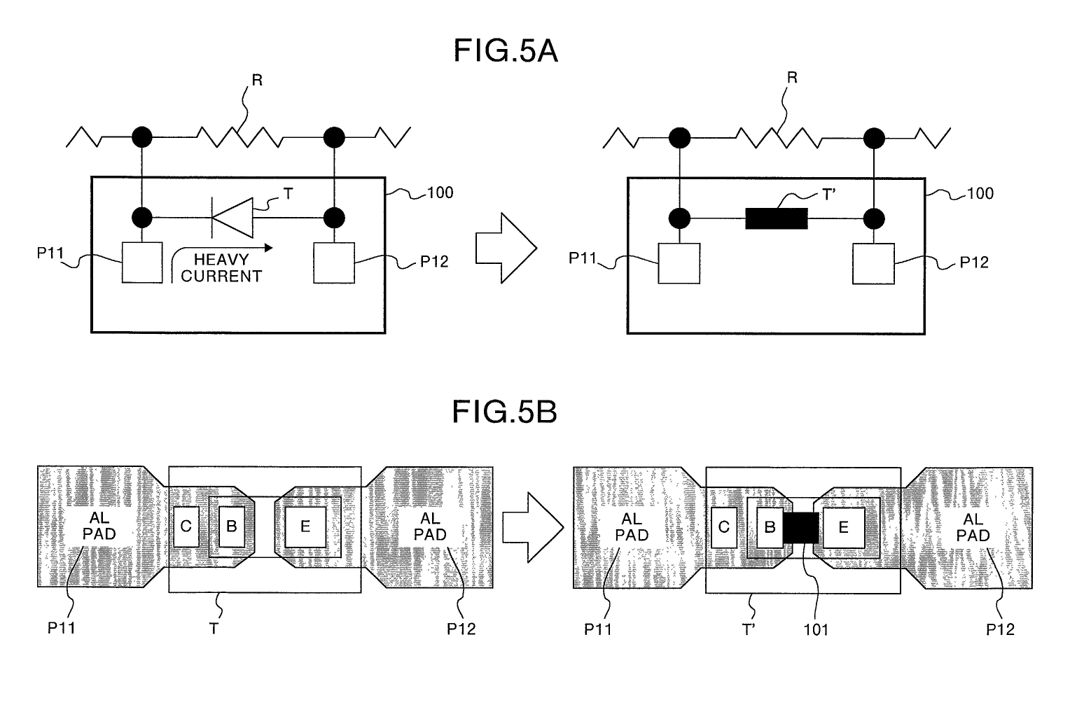

FIG. 6 is a diagram for explaining polysilicon laser trimming.

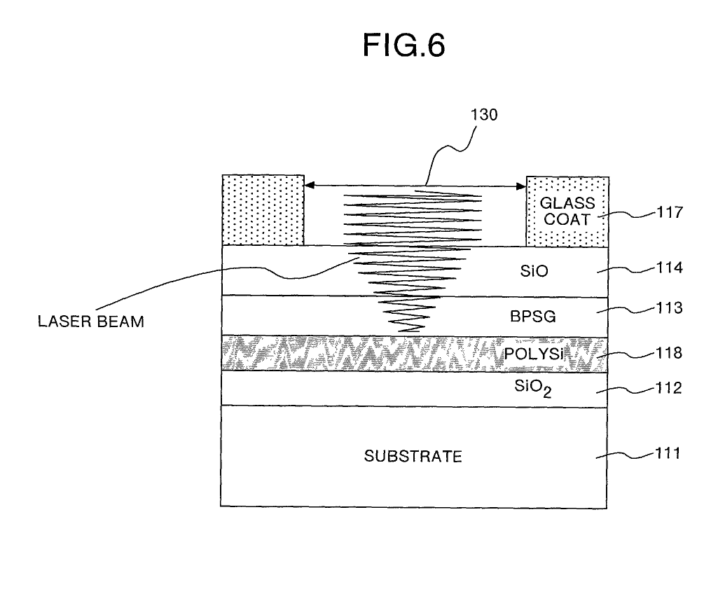

### DESCRIPTION OF THE PREFERRED EMBODIMENTS

Preferred embodiments of a semiconductor integrated circuit according to the invention will be described in detail hereinbelow with reference to the accompanying drawings. However, the invention is not limited to the embodiments.

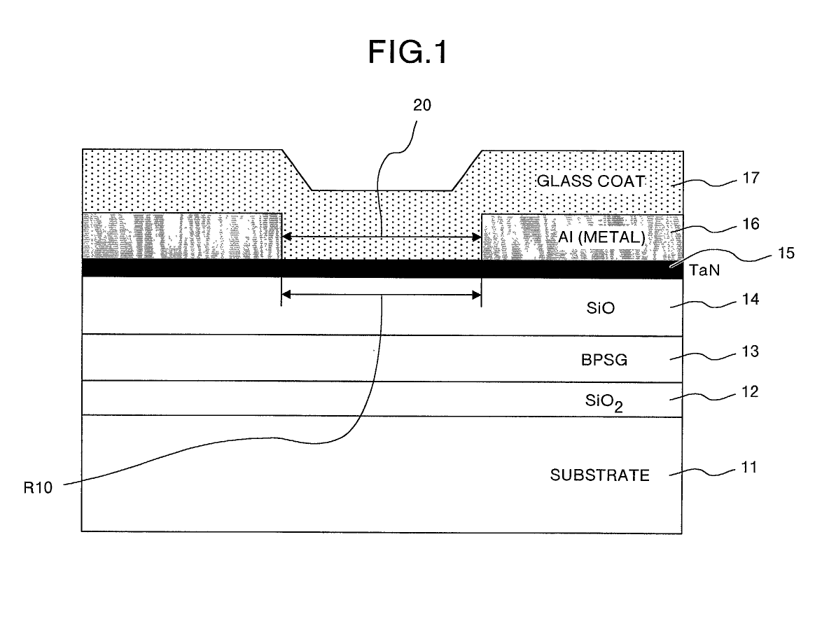

First, a semiconductor integrated circuit according to a first embodiment will be described. FIG. 1 is a diagram for explaining a trimming device in the semiconductor integrated circuit according to the first embodiment and particularly shows the layout cross section of the semiconductor integrated circuit.

In the semiconductor integrated circuit shown in FIG. 1, layers common to MOS and bipolar type devices are illustrated. The semiconductor integrated circuit has a multilayer structure in which an SiO₂ layer 12, a BPSG layer 13, and an SiO layer 14 which are insulating interlayers, a TaN layer 15, a metal wiring layer 16 made of aluminum or the like, and a glass coating layer 17 as a protective film are sequentially stacked on a silicon substrate 11.

There is a case that the TaN layer 15 is used as a barrier metal, that is, a layer to prevent a metal used in the metal wiring layer 16 which is on the TaN layer 15 from being diffused. The structure shown in FIG. 1 corresponds to this case. As the material of the metal wiring layer 16, aluminum which is technically proven, copper which is recently employed to realize low resistance, or the like can be used, but it is not especially limited here.

The embodiment is characterized in that, as shown in the diagram, in the multilayer structure having the TaN layer 15, after formation of the metal wiring layer 16, a window 20 is opened by removing a part of the metal wiring layer 16 by etching or the like to expose a part of the TaN layer 15. The exposed TaN portion functions as a resistor R10 having sheet resistance (surface resistivity of about 40 Ω/sq.) similar to that of polysilicon.

The resistor made of TaN has extremely stable physical properties and changes only about 0.05% in ten years. In the case where the dimension of the resistor is 40 μm wide and 115 μm long (at 120 Ω), it is empirically known that the resistor is burnt when about 2 watts of power is applied across the resistor.

The resistor R10 made by the TaN single layer can be therefore effectively used as a fuse for trimming. Particularly, it is important that the TaN layer is a single layer. Current trimming which will be described hereinlater is performed on condition that the TaN layer is a single layer.

In the semiconductor integrated circuit according to the first embodiment as described above, the TaN film functioning as a barrier metal of the metal wiring layer 16 is used as a single TaN layer by removing a part of the metal wiring layer 16 thereon, so that the TaN single layer portion can be used as the resistor R10 functioning as a fuse. Especially, because of the known characteristic of TaN, the resistor R10 can be sufficiently burnt by the passage of current or irradiation of a laser beam. Thus, selection of trimming methods can be widened.

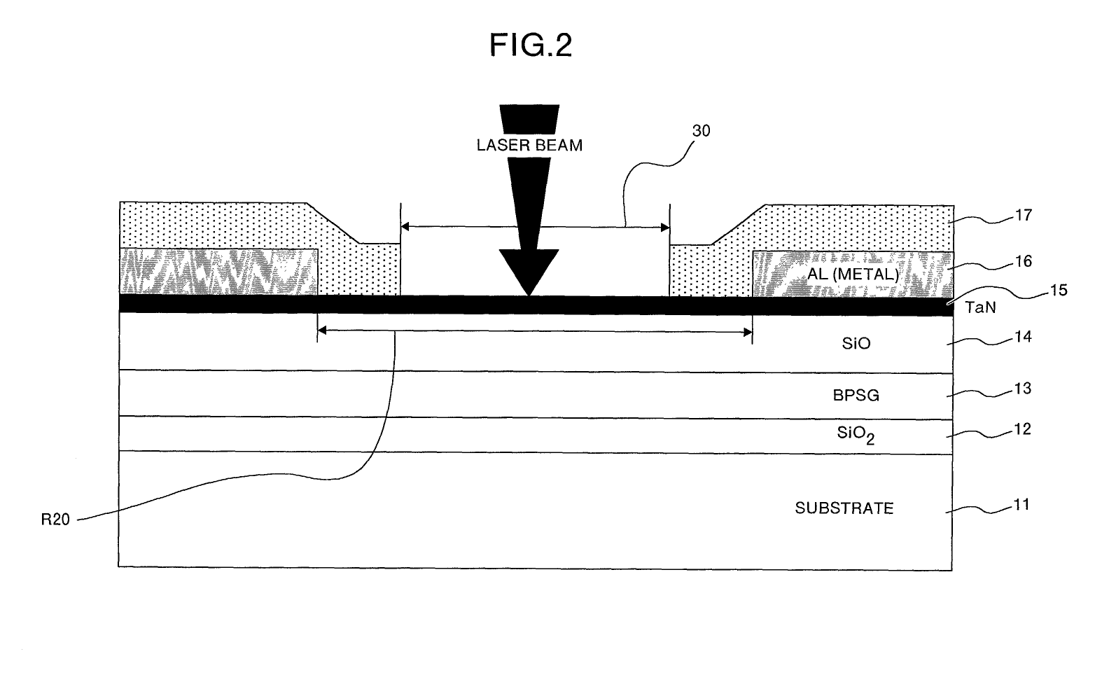

A semiconductor integrated circuit according to a second embodiment will now be described. The second embodiment relates to laser trimming in the case where the TaN single layer is used as a trimming device. FIG. 2 is a diagram for explaining laser trimming performed in the semiconductor integrated circuit according to the second embodiment and particularly shows the layout cross section of the semiconductor integrated circuit. In FIG. 2, the same reference numerals are given to the same components as those in FIG. 1 and their description will not be repeated here.

FIG. 2 is different from FIG. 1 with respect to the point that a window 30 is formed by removing a part of the glass coating layer 17 positioning on the resistor R20 made by the TaN single layer. Removal of the glass coating layer 17 can be realized by the same method as that in a process of forming a bonding pad opening. By the method, a part of the resistor R20 made by the TaN single layer is exposed. When the portion is irradiated with a laser beam from above, the laser beam can reach the TaN single layer without attenuation. That is, the initially set energy of the laser beam can be sufficiently given to the resistor R20, so that the resistor R20 can be burnt with reliability.

As described above, in the semiconductor integrated circuit according to the second embodiment, the TaN single layer portion is obtained by removing a part of the metal wiring layer 16 on the TaN layer 15 functioning as a barrier metal of the metal wiring layer 16 and removing a part of the glass coating layer 17 on the metal wiring layer 16. When the TaN single layer portion is used as a laser trimming device, the TaN single layer portion can be irradiated with a laser beam having sufficient intensity with little attenuation without requiring strict adjustment at the time of trimming. Thus, the resistor can be burnt with reliability.

Since some insulating interlayers are sandwiched between the silicon substrate 11 as an underlayer and the TaN single layer 15, the second embodiment has an advantage that the possibility that the silicon substrate is short circuited is lower than the case where the laser trimming is performed by using polysilicon as a trimming device.

Since only the TaN single layer portion is exposed and the metal wiring layer 16 remains to be covered with the glass coating layer 17, it is not concerned that the metal wiring layer 16 corrodes. Consequently, reliability of long-time operation of the semiconductor integrated circuit can be improved. As TaN itself is extremely stable as described above, even when it is exposed, it is unnecessary to concern corrosion as much as a metal used for the metal wiring layer 16.

Further, the TaN film can be removed in a wiring process and the structure of layers below the TaN film is not limited. The trimming device of the TaN single layer can be therefore formed for both the MOS type and bipolar type.

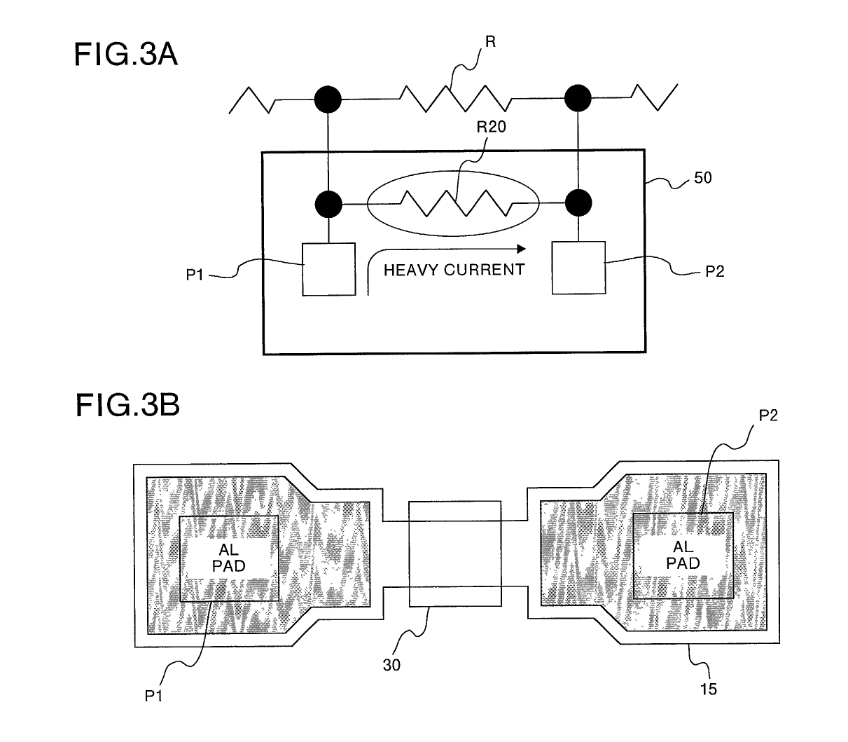

A semiconductor integrated circuit according to a third embodiment will now be described. The third embodiment relates to current trimming performed on the TaN single layer in the semiconductor integrated circuit according to the second embodiment. FIGS. 3A and 3B are diagrams for explaining the current trimming in the semiconductor integrated circuit according to the third embodiment.

Referring to FIG. 3A, a resistor R is a device for determining the characteristic of a device required to have the absolute precision and is, for example, a resistor for setting the gain of an operational amplifier. A resistor R20 functioning as a trimming device is connected in parallel to the resistor R. The resistor R20 is the same one provided as the TaN single layer portion in the structure shown in FIG. 2. FIG. 3B is a diagram showing the layout of a portion corresponding to a thick-lined frame 50 in FIG. 3A. In FIG. 3B, reference numeral 30 corresponds to the window 30 shown in FIG. 2.

In FIGS. 3A and 3B, the current trimming is performed by passing a heavy current between the pads P1 and P2 led from both ends of the resistor R20. By the passage of the heavy current, the resistor R20, that is, the TaN single layer portion is burnt by the rise in temperature of the portion.

Consequently, as compared with the conventional Zener zapping, although there is a difference of short-circuiting or breakdown, in the semiconductor integrated circuit according to the third embodiment, it is sufficient to simply grasp the minimum current to burn the TaN single layer portion, and adjustment of a current which requires precision is unnecessary.

It has been described in the first embodiment that when the dimension of the TaN film is 40 μm wide and 115 μm long (at 120 Ω), it is known that the resistor is burnt by application of about two watts of power across the resistor. In order to change the point at which the resistor is burnt, for example, the shape of the resistor is changed.

As described above, in the semiconductor integrated circuit according to the third embodiment, the TaN single layer portion in the semiconductor integrated circuit according to the second embodiment is used as a trimming device for current trimming. When the minimum current with which the TaN single layer portion can be burnt is known, high-precision current adjustment is not required and, moreover, it is unnecessary to examine the reliability of a processed device to be adjusted.

As described in the second embodiment, the window 30 is provided by removing the glass coating layer 17 on the TaN single layer portion. Consequently, a crack in the glass coating layer 17 by sudden heating at the time of burning can be also avoided.

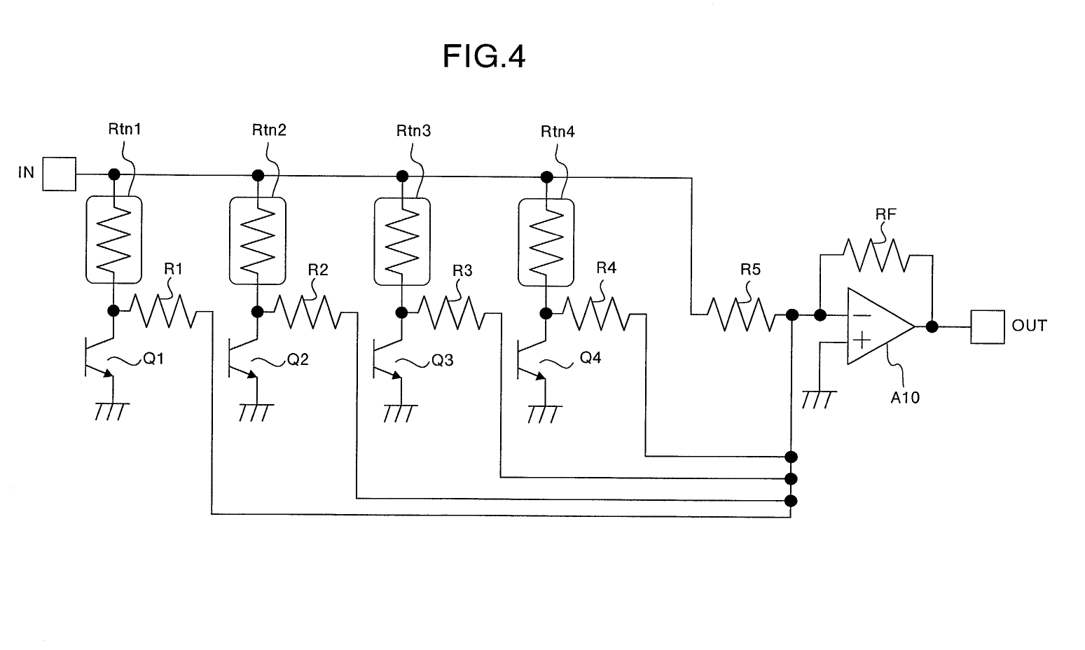

A semiconductor integrated circuit according to a fourth embodiment will now be described. The fourth embodiment is characterized in that the pads P1 and P2 provided in positions where current trimming is desired to be performed in the third embodiment are made unnecessary by connecting transistors having high current driving ability. FIG. 4 is a diagram showing a configuration example of the semiconductor integrated circuit according to the fourth embodiment and particularly relates to a case where the gain of the operational amplifier is trimmed.

The circuit shown in FIG. 4 is constructed by an operational amplifier A10, a first resistor RF for determining the gain of the operational amplifier A10, and a second resistor group. The second resistor group is constructed in such a manner that a first series resistors having resistors Rtn1 and R1, a second series resistor having resistors Rtn2 and R2, a third series resistor having resistors Rtn3 and R3, a fourth series resistor having resistors Rtn4 and R4, and a resistor R5 are connected in parallel. Each of the resistors Rtn1 to Rtn4 is provided as a TaN single layer portion like the resistor R20 shown in the second embodiment.

That is, in this state, the gain of the operational amplifier A10 is determined by a resultant resistance value determined by the first to fourth series resistors and the resistor R5 and the resistance value of the resistor RF.

In the first series resistor, one end of a transistor Q1 (collector terminal of an NPN transistor in the diagram) having high current driving ability is connected to a connection point of the resistors Rtn1 and R1. The other end (emitter terminal) of the transistor Q1 is connected to the ground. As shown in the diagram, in a manner similar to the first series resistor, transistors Q2 to Q4 are connected in the other series resistors.

Consequently, for example, in the first series resistor, by applying a voltage exceeding a threshold level to a control terminal (base terminal in the diagram) of the transistor Q1, the transistor Q1 is turned on and a heavy current can be passed to the resistor Rtn1. That is, by turning on the transistor Q1, the resistor Rtn1 can be burnt. In the other second to fourth series resistors, similar operation is performed.

When the manufactured operational amplifier A10 does not satisfy the designed gain characteristic, in order to correct the gain to the characteristic as designed, that is, to change the resultant resistance value, the resistors R1 to R4 are selectively eliminated by turning on the transistors Q1 to Q4. For example, if the operational amplifier A10 displays the target characteristic by eliminating the resistor R1, the transistor Q1 is turned to burn the resistor Rtn1, thereby opening the resistor R1.

As described above, in the semiconductor integrated circuit according to the fourth embodiment, by connecting a transistor of a high current driving ability to a resistor provided as a TaN single layer portion and turning on the transistor, a heavy current is passed to the resistor to burn the resistor. It is therefore unnecessary to dispose trimming pads led from both ends of the resistor near the trimming position as shown in FIG. 3. In such a manner, the limitation on the chip layout can be flexibly dealt with.

Since each of the laser trimming described in the second embodiment and the current trimming described in the third and fourth embodiments uses the TaN single layer having the structure shown in FIG. 2, by providing additional elements such as pads and transistors shown in FIGS. 3A and 3B and 4 which can be used for current trimming, either laser trimming or current trimming can be arbitrarily selected. That is, both the laser trimming and current trimming can be performed. It is advantageous in the case where when there is a resistor which is left untrimmed by the current trimming, the resistor is trimmed by the laser trimming, the case where when a laser trimming apparatus has a trouble or cannot be used because it is occupied, the current trimming is performed as alternative means, or the opposite case where when the current trimming cannot be used, the laser trimming is performed. Thus, the reliability and mass productivity can be improved.

As described above, according to the semiconductor integrated circuit of this invention, the tantalum nitride single layer portion is obtained by removing a part of the metal wiring layer provided on the tantalum nitride layer functioning as a barrier metal of the metal wiring layer. Consequently, an effect such that the tantalum nitride single layer portion can be used as a resistor for trimming which functions as a fuse is produced.

Furthermore, the resistor for trimming is obtained by exposing one of the faces of the tantalum nitride single layer portion, the resistor for trimming is used as a laser trimming device which is burnt when the one face is irradiated with a laser beam. Therefore, an effect such that the tantalum nitride single layer portion can be irradiated with a laser beam having sufficient intensity which is hardly attenuated and the resistor for trimming can be burnt with reliability without requiring strict adjustment at the time of trimming is produced.

Furthermore, the resistor for trimming is made by a single layer portion of the tantalum nitride film, and the electrode pads led from both ends of the resistor for trimming are provided. Consequently, the following effects are produced. The resistor for trimming can be used as a current trimming device which is burnt when a current is passed to the electrode pads. Only by knowing the minimum current by which the tantalum nitride single layer portion can be burnt, high-precision current adjustment is not necessary. Since one of the faces is exposed, a problem of a crack which occurs due to heat generated by the current when other layers such as the glass coating layer are stacked on the tantalum nitride film can be also avoided.

Furthermore, the resistor for trimming is made by exposing one of the faces of the single layer portion of the tantalum nitride film and the electrode pads led from both ends of the resistor for trimming are provided. The resistor for trimming can be therefore used both as a laser trimming device which is burnt when the face is irradiated with a laser beam and a current trimming device which is burnt when a current is passed to the electrode pads. Consequently, it is advantageous in the case where when there is a resistor which is left untrimmed by the current trimming, the resistor is trimmed by the laser trimming, the case where when a laser trimming apparatus has a trouble or cannot be used because it is occupied, the current trimming is performed as alternative means, and the like. Thus, an effect such that the reliability and mass productivity can be improved is produced.

Furthermore, the transistor for passing a current is connected to the resistor for trimming which is provided as the single layer portion of the tantalum nitride film, of which one face is exposed. By turning on the transistor, the resistor trimming is burnt. Consequently, it is unnecessary to dispose the electrode pads led from both ends of the resistor for trimming near the trimming part. An effect such that the limitation on the chip layout can be flexibly addressed is produced.

Furthermore, the transistor for passing a current is connected to the resistor for trimming provided as the single layer portion of the tantalum nitride film, of which one face is exposed. The resistor for trimming is used both as a laser trimming device which is burnt when the face is irradiated with a laser beam and as a current trimming device which is burnt when the transistor is turned on. Consequently, it is unnecessary to dispose the electrode pads adjacent to the trimming part, so that the limitation on the chip layout can be flexibly addressed. It is advantageous in the case where when there is a resistor which is left untrimmed by the current trimming, the resistor is trimmed by the laser trimming, the case where when a laser trimming apparatus has a trouble or cannot be used because it is occupied, the current trimming is performed as alternative means, and its opposite case. Thus, an effect such that the reliability and mass productivity can be improved is produced.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor integrated circuit having a tantalum nitride film formed as a barrier metal of a metal wiring layer, said semiconductor integrated circuit comprising:
a resistor for trimming made by a single layer portion of the tantalum nitride film formed by removing a part of said metal wiring layer.

2. The semiconductor integrated circuit according to claim 1, wherein said resistor for trimming is the single layer portion of the tantalum nitride film, one of faces of the single layer portion is exposed, and said resistor is burnt when said one face is irradiated with a laser beam.

3. The semiconductor integrated circuit according to claim 1, further comprising electrode pads led from both ends of said resistor for trimming,
wherein said resistor for trimming is made by a single layer portion of the tantalum nitride film, one of faces of the single layer portion is exposed, and said resistor for trimming is burnt when a current is passed to said electrode pads.

4. The semiconductor integrated circuit according to claim 1, further comprising electrode pads led from both ends of said resistor for trimming,
wherein said resistor for trimming is made by a single layer portion of the tantalum nitride film, one of faces of the single layer portion is exposed, and said resistor for trimming is burnt when said face is irradiated with a laser beam or a current is passed to said electrode pads.

5. The semiconductor integrated circuit according to claim 1, further comprising at least one transistor for passing a current to said resistor for trimming,
wherein said resistor for trimming is made by a single layer portion of the tantalum nitride film, one of faces of the single layer portion is exposed, and said resistor for trimming is burnt when said transistor is turned on.

6. The semiconductor integrated circuit according to claim 1, further comprising at least one transistor for passing a current to said resistor for trimming,
wherein said resistor for trimming is made by a single layer portion of the tantalum nitride film, one of faces of the single layer portion is exposed, and said resistor for trimming is burnt when said face is irradiated with a laser beam or said transistor is turned on.
